(19) United States
(12) Patent Application Publication
(10) Pub. No.: US 2012/0105125 A1
(43) Pub. Date: May 3, 2012

(54) ELECTRONIC CIRCUIT AND METHOD FOR OPERATING A CIRCUIT IN A STANDBY MODE AND IN AN OPERATIONAL MODE

(76) Inventors: Michael Priel, Hertzelia (IL); Anton Rozen, Gedera (IL); Yossi Shoshani, Gan Yavne (IL)

(21) Appl. No.: 12/938,493

(22) Filed: Nov. 3, 2010

(51) Int. Cl. H03L 5/00

(52) U.S. Cl. 327/306

(57) ABSTRACT

A method and an electronic circuit, the electronic circuit includes: a first circuit; a leakage measurement circuit arranged to determine a leakage level of the first circuit when the first circuit is in a standby mode, and to determine an information maintenance level of a supply voltage in response to the leakage level; and a voltage supply circuit arranged to provide to the first circuit a supply voltage of a functional level when the first circuit is in a functional mode, and to provide to the first circuit a supply voltage of the information maintenance level when the first circuit is in the standby mode; wherein the first circuit is arranged to maintain information when provided with the supply voltage of the information maintenance level.

### FIELD OF THE INVENTION

This invention relates to an electronic circuit and a method for operating a circuit in a standby mode and in an operational mode.

### BACKGROUND OF THE INVENTION

Integrated circuits are manufactured by a highly complex manufacturing process. The manufacturing process starts by manufacturing semiconductor wafers, which are then provided with electronic circuits in a manner that a wafer includes multiple dice, each die having a given electronic circuit or electronic device. Thereafter, semiconductor wafer is diced and the dices are packaged to provide integrated circuits, each includes a single die. However, the parameters of the manufacturing process may exhibit variations, both over time and space. This may introduce differences in various electrical parameters of the integrated circuits, and even between different integrated circuits that include dices that belonged to the same semiconductor wafer.

Typically, a process window is defined which sets an acceptable range of variation for these electrical parameters. The process window may define, for example, minimal and maximal operating frequencies of integrated circuits as well as minimal and maximal leakage of each integrated circuit.

FIG. 1 illustrates a relationship between operating frequencies and leakage values of integrated circuit. Line 10 of FIG. 1 illustrates an exponential relationship between operating frequencies and leakage values. In the example of FIG. 1, the process window is defined by point A and C.

Point A 12 on line 10 defines the minimum for the range of acceptable operating frequency and current leakage, and represents integrated circuits classified as “worst case integrated circuits”, which have the lowest operating frequency (Fa 22), have the lowest leakage (la 32), and have the highest threshold voltage. Point B 14 is situated in the process window. Point B represents integrated circuits classified as “typical case integrated circuits”, which have a typical operation frequency (Fb 24), have a typical leakage (lb 34), and have a typical threshold voltage. Point C on line 10 defines the maximum for both the range of acceptable operating frequency and the current leakage. Point C 16 represents integrated circuits classified as “best case integrated circuits”, which have the highest operating frequency (Fc 26), have the highest leakage (lc 36) and have the lowest threshold voltage.

Various strategies have been developed to help reducing power consumption of an integrated circuit while maintaining performance and functionality. For example, the integrated circuit can be maintained in a standby mode from time to time, thus reducing the power consumption of the integrated circuit. Typically, when in standby mode the integrated circuit should maintain information, such as information generated when the integrated circuit was in a functional mode.

However in order to maintain the information, the integrated circuit requires a supply voltage level not lower than an information maintenance level. This information maintenance level may differ from one integrated circuit to the other and may also be dependent on temperature. For example, a best case integrated circuit may have a lower information maintenance level than a worst case integrated circuit or a typical case integrated circuit. Yet for another example, at higher temperatures, the information maintenance levels increases as well.

The information maintenance level is normally defined regardless of the process variations and set to the information maintenance level of worst case integrated circuits at the highest allowed operating temperature. Accordingly, integrated circuits that are not worst case integrated circuits and, additionally or alternatively, are not at the highest allowable temperature, receive a supply voltage (when in the standby mode) that is higher than necessary to maintain information. Thus, the leakage of most integrated circuits is higher than desired.

### SUMMARY OF THE INVENTION

The present invention provides a method and an electronic circuit as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the FIGs. are illustrated for simplicity and clarity and have not necessarily been drawn to scale.

FIG. 1 shows a graph which illustrates a relationship between operating frequencies and leakage values of integrated circuit that belong to a certain process window;

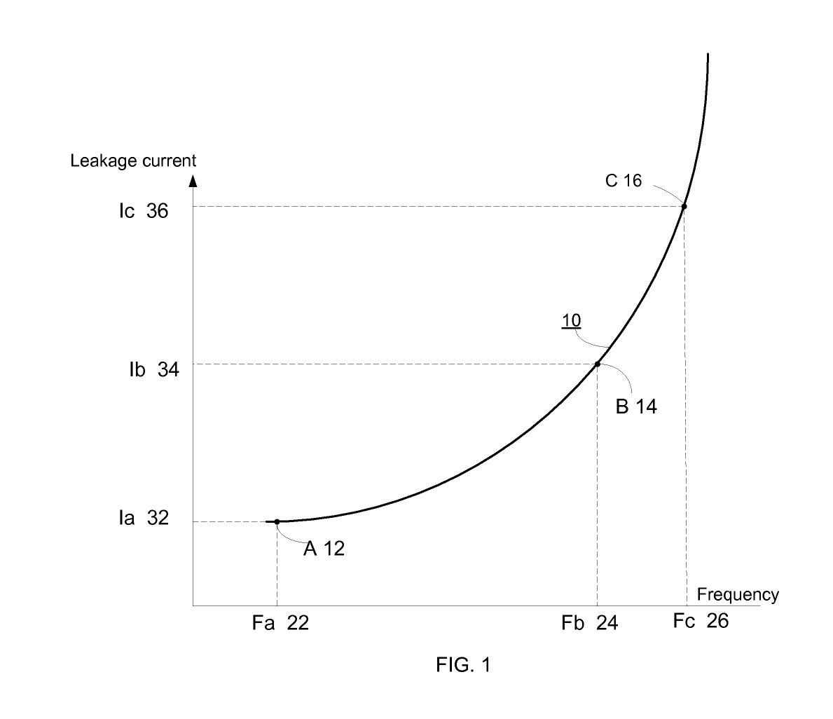

FIG. 2 schematically shows a block diagram of a first example of an embodiment of an electronic circuit;

FIG. 3 schematically shows a block diagram of a second example of an embodiment of an electronic circuit;

FIG. 4 schematically shows an example of a timing diagram suitable for the examples of FIGS. 2 and 3; and

FIG. 5 schematically shows a flow chart of an example of a method for operating a circuit in an idle mode and in a functional mode.

### DETAILED DESCRIPTION OF THE PREFERRED EMBODIMENTS

Because the illustrated embodiments of the present invention may for the most part, be implemented using electronic components and circuits known to those skilled in the art, details will not be explained in any greater extent than that considered necessary for the understanding and appreciation of the underlying concepts of the present invention and in order not to obfuscate or distract from the teachings of the present invention.

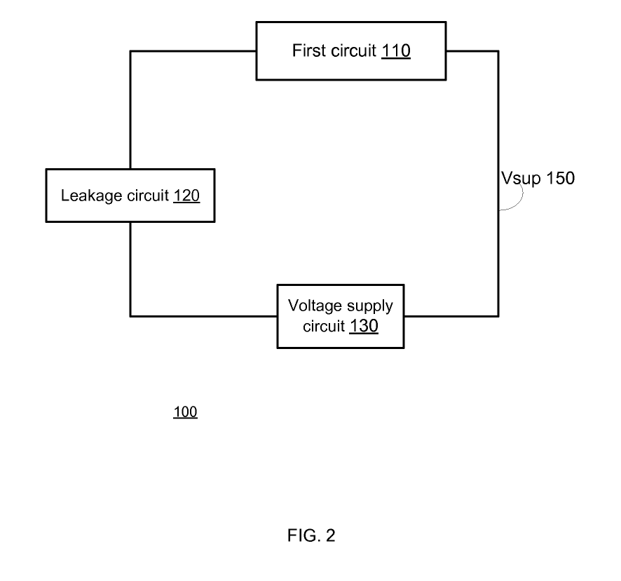

FIG. 2 schematically shows an example of an embodiment of an electronic circuit 100. The electronic circuit 100 can be a mobile phone, a media player or any other rechargeable device. Alternatively, the electronic circuit 100 can be a part of a mobile phone, a media player or any other rechargeable device.

Electronic circuit 100 may include a first circuit 110, a leakage measurement circuit 120 and a voltage supply circuit 130. The first circuit 110, the leakage measurement circuit 120 and the voltage supply circuit 130 are connected to each other.

The first circuit 110 can be an integrated circuit or a part of an integrated circuit, for example the first circuit can be a processor core, or a part thereof that is switched off in the standby mode. The first circuit 110 can operate in a functional mode and in a standby mode. In the functional mode the first circuit 110 may perform its primary function, such as processing or storing information. When in the standby mode, the first circuit 110 maintains information generated before entering the standby mode and does not perform its primary function, e.g. does not perform any processing.

The leakage measurement circuit 120 is arranged to (a) determine a leakage level of the first circuit, when the first circuit is in a standby mode, and (b) determine the information maintenance level of a supply voltage in response to the leakage level.

The leakage measurement circuit 120 can determine the leakage level by measuring the leakage level, and additionally or alternatively, by estimating the leakage level. The leakage measurement circuit 120 can e.g. comprise a dedicated circuit of which a parameter, e.g. frequency, depends on the leakage current of the first circuit 110, such as a ring-oscillator (as described in U.S. Pat. No. 6,882,172) or other suitable circuit. For example, the leakage level of the first circuit 110 can be measured by a current meter that is connected to the first circuit 110 or by a voltage meter that measures a voltage drop on a resistor that is connected between the first circuit 110 and the ground (or another reference point outside the first circuit 110). The circuit 120 may also comprise a part of the first circuit 110, such as a test circuit therein or the entire first circuit. For example, the leakage measurement circuit 120 may comprise the first circuit 110 and a control circuit, not shown, which can switch the clock(s) for the first circuit 110 off and measure the voltage over two nodes of the circuit, e.g. between different pins. Yet for another example, the leakage level can be evaluated by analyzing an output signal that is generated by a reference circuit. The reference circuit can include a reference transistor that is manufactured by the same process and under substantially the same conditions as the first circuit and also include a leakage susceptible oscillator that has an oscillation frequency that reflects the leakage level of the reference transistor.

The leakage measurement circuit 120 can determine the leakage level and determine the information maintenance level at least once during the lifespan of the first circuit 110. These determinations (of the leakage level and of the information maintenance level) can be executed in a repetitive manner, in response to an event (such as a change that is above a predefined threshold in the temperature of the first circuit 110), in random manner, in a pseudo random manner or a combination of any of the previously mentioned manners. For example, the leakage measurement circuit 120 can perform these determinations each time the first circuit enters the standby mode. Yet for another example, the leakage measurement circuit 120 can perform these determinations if a predefined time period has elapsed from the last time these determinations were made.

The leakage measurement circuit 120 can further comprise a measurement unit which measures the parameter and provides the measured value to a supply control unit, which can determine the information maintenance level and control the voltage supply circuit to provide a corresponding supply voltage in the standby mode. The information maintenance level may for example be determined based on a mapping between leakage levels and information maintenance levels. For instance, the information maintenance level may be determined by selecting from a table a value for the information maintenance level that is associated with the measured leakage level. Alternatively, a mathematical model for the relationship between leakage and the information maintenance level may have been predetermined and the circuit 120 may determine the suitable level by performing a calculation thereof using the mathematical model. The mapping can be provided by the manufacturer of the integrated circuit and be fed to the leakage measurement circuit before the electrical circuit is shipped from the manufacturer facilities. Alternatively, the mapping can be provided (or be updated) after a completion of this shipment.

The leakage measurement circuit 120 can inform the voltage supply circuit 130 what is the information maintenance level. The voltage supply circuit 130 is arranged to provide to the first circuit 110 a supply voltage (Vsup 150) of a functional level when the first circuit is in a functional mode, and to provide to the first circuit 110 a supply voltage of the information maintenance level when the first circuit 110 is in the standby mode. The voltage supply circuit 130 can belong to the same integrated circuit as the first circuit 110, and e.g. be a supply circuit for the processor core integrated in the same processor, but these components can belong to different integrated circuits and the voltage supply circuit 130 may e.g. be part of a separate power management integrated circuit.

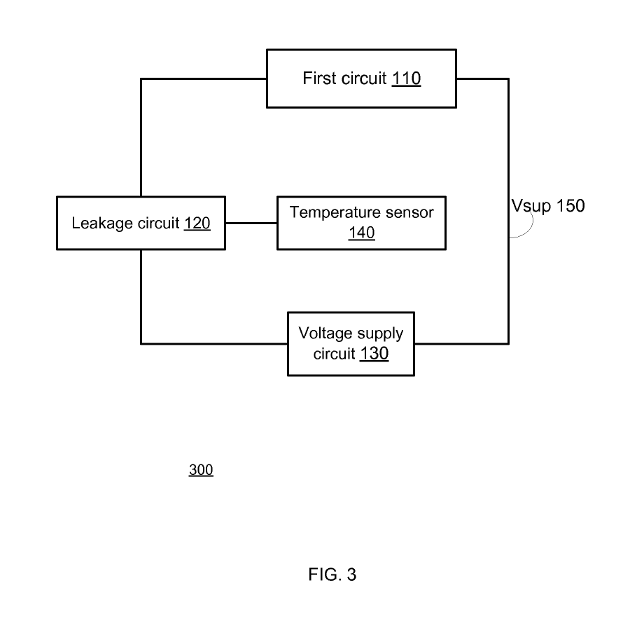

FIG. 3 schematically shows an example of an embodiment of an electronic circuit 300. The electronic circuit 300 may include a first circuit 110, a leakage measurement circuit 120, a voltage supply circuit 130 and a temperature sensor 140. Elements in FIG. 3 similar to those described in the context of FIG. 2 will not be described in further detail herein below.

The temperature sensor 140 is arranged to sense the temperature of the first circuit 110 and to provide to the leakage measurement circuit 120 temperature information about the temperature of the first circuit 110.

The temperature information can trigger the determinations of the leakage value and of the information maintenance values. For example, a change in the temperature of the first circuit 110 that is above a predefined threshold may trigger the determinations.

Additionally or alternatively, the leakage measurement circuit 120 may be arranged to estimate the information maintenance level based on the temperature information.

For example, the leakage measurement circuit 120 can determine the type of the first circuit 110 by correlating between the leakage level of the first circuit 110 and the temperature information. The type of the first circuit 110 indicates what were the manufacturing parameters that existed during the manufacturing process of the first circuit 110.

Once the type of the first circuit 110 is determined the leakage measurement circuit 120 can, for example, determine what will be the information maintenance level that will guarantee that the first circuit 110 will maintain information regardless of the temperature of the first circuit 110.

Yet for another example, the leakage measurement circuit 120 can determine what will be the information maintenance level that will guarantee that the first circuit 110 will maintain information while the temperature of the first circuit 110 is within a predefined temperature range and the leakage measurement circuit 120 can trigger a new set of determination once the temperature of the first circuit 110 exceeds this predefined temperature range.

Although in the example of FIG. 3 the temperature sensor 140 is coupled to the leakage measurement circuit 120, the leakage measurement circuit 120 can include the temperature sensor 140.

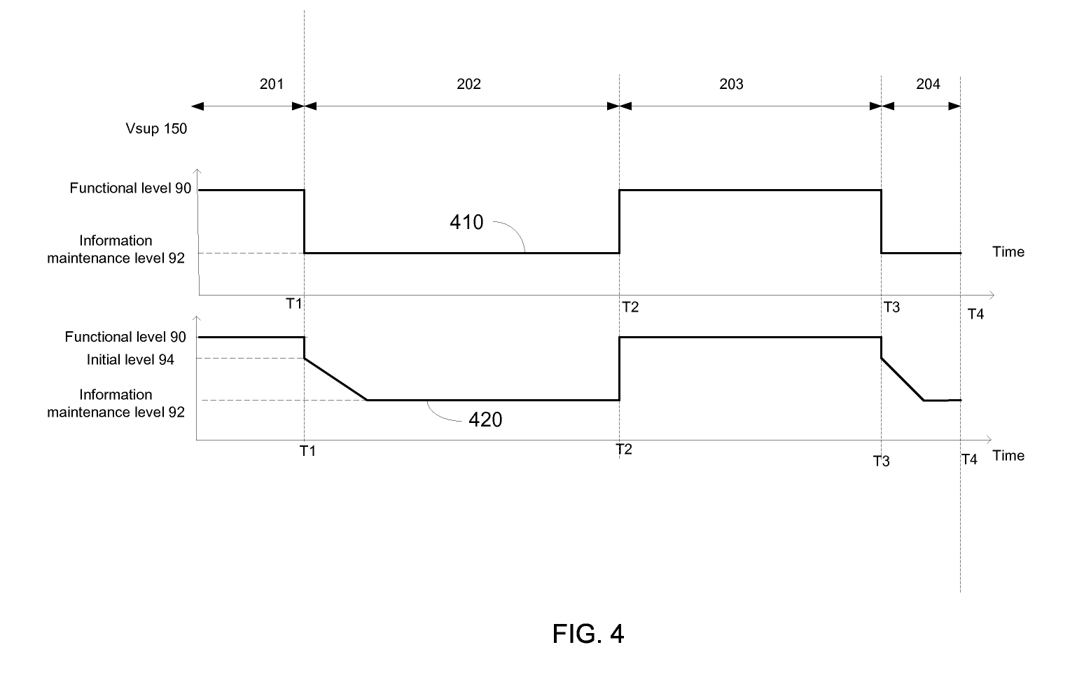

FIG. 4 schematically shows a timing diagram which illustrates different examples, illustrated by curves 410 and 420, illustrates a different example of an embodiment of a supply voltage Vsup 150, suitable for the example of FIG. 2.

During a first functional period 201 (between points of time T0 and T1) the first circuit 110 operates in a functional mode. During the first functional period 201 the level of Vsup 150 is set to a functional level 90. The first functional period 201 is followed by a first standby period 202 (between points of time T1 and T2). During the first standby period 202 the level of Vsup 150 can be set to an information maintenance level 92—as illustrated by curve 410.

Alternatively, at the beginning of the first idle period 202 the level of Vsup 150 can be set of an initial level 94 and then be decremented till reaching the information maintenance level 92—as illustrated by curve 420.

The first idle period 202 is followed by a second idle period 203 (between points of time T2 and T3). During the second functional period 203 the level of Vsup 150 is set to the functional level 90.

The second functional period 203 is followed by a second idle period 204 (between points of time T3 and T4). During the second idle period 204 the level of Vsup 150 can be set to an information maintenance level 92—as illustrated by curve 410.

Alternatively, at the beginning of the second idle period 204 the level of Vsup 150 can be set of an initial level 94 and then be decremented till reaching the information maintenance level 92—as illustrated by curve 420.

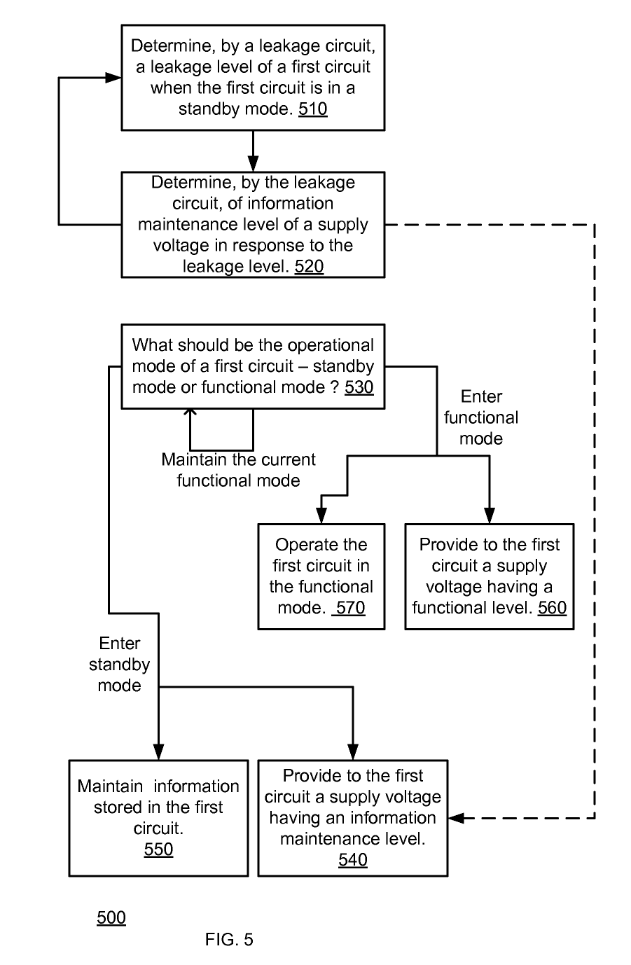

Referring to FIG. 5, a method 500 for operating a circuit in a functional mode and in a standby mode is illustrated. The method may, as explained below in further detail, include: (i) determining, by a leakage measurement circuit, a leakage level of the first circuit when the first circuit is in a standby mode; (ii) determining, by the leakage measurement circuit, an information maintenance level of a supply voltage in response to the leakage level; wherein the first circuit is arranged to maintain information when provided with a supply voltage of the information maintenance level; (iii) determining whether the first circuit should enter a functional mode or should enter a standby node; (iv) when the first circuit should enter the standby mode, providing to the first circuit a supply voltage of the information maintenance level; and maintaining information stored in the first circuit; (vii) when the first circuit should enter the functional mode, providing to the first circuit a supply voltage of a functional level; and operating the first circuit in the functional mode.

FIG. 5 includes multiple boxes that illustrate various stages. It is noted that these stages can be executed in parallel to each other, in an overlapping or at least partially overlapping manner or in a non-overlapping manner. It is further notes that the order of execution of these stages may deviate from the order of boxes in FIG. 5.

Method 500 may stars by a determination (box 510), by a leakage measurement circuit, a leakage level of a first circuit when the first circuit is in a standby mode.

The determination of the leakage level is followed by a determination (box 520), by the leakage measurement circuit, of information maintenance level of a supply voltage in response to the leakage level. The first circuit is arranged to maintain information when provided with a supply voltage of the information maintenance level.

These determination can be performed once or more during the lifespan of the first circuit.

In the example of FIG. 5, these determinations are illustrated as being followed by another determination (box 530) of whether to (i) to maintain the first circuit in its current operational mode or to change the operational mode and either (ii) enter a standby mode and provide (box 540) to the first circuit a supply voltage of the information maintenance level; and maintain (box 550) information stored in the first circuit; or (iii) enter a functional mode and provide (box 560) to the first circuit a supply voltage of a functional level, and operate (box 570) the first circuit in the functional mode.

Although not explicitly illustrated in FIG. 5, the determinations of the leakage level (box 510) and of the information maintenance level (box 520) can be executed while the first circuit is in either one of the functional mode and the standby mode.

In the foregoing specification, the invention has been described with reference to specific examples of embodiments of the invention. It will, however, be evident that various modifications and changes may be made therein without departing from the broader spirit and scope of the invention as set forth in the appended claims. For example, the power management circuit may belong to the same integrated circuit as the first circuit or may belong to another integrated circuit.

Furthermore, each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein may be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

In the claims, the word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

We claim:

1. An electronic circuit, comprising:
a first circuit having a functional mode and a standby mode;
a leakage measurement circuit connected to the first circuit, for determining a leakage level of the first circuit when the first circuit is in a standby mode, and to determine an information maintenance level of a supply voltage, suitable for the first circuit to maintain information in the standby mode, at least partial based on the determined leakage level; and
a voltage supply circuit connected to the first circuit to provide a supply voltage of a functional level when the first circuit is in the functional mode, and to provide to the first circuit a supply voltage of the information maintenance level when the first circuit is in the standby mode;

2. The electronic circuit according to claim 1, wherein the leakage measurement circuit is arranged to determine the information maintenance level based on a mapping between leakage levels and information maintenance levels.

3. The electronic circuit according to claim 1, wherein the voltage supply circuit is arranged to provide a voltage supply of an initial level when the first circuit enters the standby mode and to reduce the level of the supply level until reaching the information maintenance level.

4. The electronic circuit according to claim 1, wherein the leakage measurement circuit is arranged to measure the leakage of the first circuit when the first circuit is in the standby mode.

5. The electronic circuit according to claim 1, wherein the leakage measurement circuit is arranged to estimate the leakage of the first circuit when the first circuit is in the standby mode.

6. The electronic circuit according to claim 1, further comprising a temperature sensor arranged measure a temperature of the first circuit and to provide to the leakage measurement circuit temperature information about the temperature of the first circuit; wherein the leakage measurement circuit is arranged to determine the information maintenance level in response to the temperature information.

7. The electronic circuit according to claim 1, wherein the information maintenance level is a minimal level of the supply voltage that allows the first circuit to maintain the information at a current temperature of the first circuit.

8. The electronic circuit according to claim 1, wherein the information maintenance level is a minimal level of the supply voltage that allows the first circuit to maintain the information regardless of a temperature of the first circuit.

9. A method for operating a first circuit having a functional mode and a standby mode, the method comprising:
determining, by a leakage measurement circuit, a leakage level of the first circuit when the first circuit is in the standby mode;
determining, by the leakage measurement circuit, an information maintenance level of a supply voltage, suitable for the first circuit to maintain information in the standby mode, at least partial based on the determined leakage level;
determining whether the first circuit should enter a functional mode or should enter a standby node;
when the first circuit should enter the standby mode:
providing to the first circuit a supply voltage of the information maintenance level; and
maintaining information stored in the first circuit; when the first circuit should enter the functional mode:
providing to the first circuit a supply voltage of a functional level; and
operating the first circuit in the functional mode.

10. The method according to claim 9, comprising determining the information maintenance level based on a mapping between leakage levels and information maintenance levels.

11. The method according to claim 9, comprising providing a voltage supply of an initial level when the first circuit enters the standby mode and reducing the level of the supply level until reaching the information maintenance level.

12. The method according to claim 9, comprising measuring the leakage of the first circuit when the first circuit is in the standby mode.

13. The method according to claim 9, comprising estimating the leakage of the first circuit when the first circuit is in the standby mode.

14. The method according to claim 9, comprising measuring a temperature of the first circuit, providing temperature information about the temperature of the first circuit; and determining the information maintenance level in response to the temperature information.

15. The method according to claim 9, wherein the information maintenance level is a minimal level of the supply voltage that allows the first circuit to maintain the information at a current temperature of the first circuit.

16. The method according to claim 9, wherein the information maintenance level is a minimal level of the supply voltage that allows the first circuit to maintain the information regardless of a temperature of the first circuit.

17. The method according to claim 9, comprising determining the information maintenance level of the supply voltage each time the first circuit enters the standby mode.

18. The method according to claim 9, comprising determining the information maintenance level of the supply voltage during a manufacturing process of the first circuit.
